(19) United States
(12) Patent Application Publication
(10) Pub. No.: US 2015/0242057 A1
(43) Pub. Date: Aug. 27, 2015

(54) TECHNIQUE FOR GENERATING LOCALIZED LIGHT SOURCE FOR AN EMBEDDED OPTICAL SENSOR ARRAY

(71) Applicant: SAMSUNG DISPLAY CO., LTD., Yongin-City (KR)

(72) Inventors: Jennifer Galela, San Carlos, CA (US); Jiuzhi Xue, Broomfield, CO (US)

(21) Appl. No.: 14/630,030

(22) Filed: Feb. 24, 2015

Related U.S. Application Data
(60) Provisional application No. 61/945,754, filed on Feb. 27, 2014.

(51) Int. Cl. G06F 3/042; H01L 51/52; G06F 3/041; H01L 27/32

(52) U.S. Cl. CPC G06F 3/0428; H01L 27/323; H01L 51/5256; H01L 27/3227; G06F 3/0412; G06F 2203/04109; G06F 2203/04105

(57) ABSTRACT

A system for detecting contact of an object with a display. The system may include a light emitting sheet on the display, the light emitting sheet being configured to emit light when the object is in contact with a point on the sheet and an optical detector in the display, which may be used to detect the emitted light and to locate the point of contact.

### CROSS-REFERENCE TO RELATED APPLICATION(S)

The present application claims priority to and the benefit of U.S. Provisional Application No. 61/945754, filed Feb. 27, 2014, entitled “TECHNIQUE FOR GENERATING LOCALIZED LIGHT SOURCE FOR AN EMBEDDED OPTICAL SENSOR ARRAY”, the entire content of which is incorporated herein by reference.

### FIELD

One or more aspects of embodiments according to the present invention relate to interactive displays, and more particularly to a system and method of detecting contact of an object with a display.

### BACKGROUND

Displays that can sense contact of an external object, e.g., a user's finger, may be used to enable various applications in which users interact with images displayed on a display screen. Some related art describes methods of detecting an external object, and its location on or near the display, relying on illuminating a volume in front of the display, and detecting reflections from the object optically. Such methods may consume unacceptable amounts of power. Thus, there is a need for a power-efficient system and method for sensing contact of an object with a display.

### SUMMARY

Aspects of embodiments of the present invention are directed toward a system for detecting contact of an object with a display. The system may include a light emitting sheet on the display and an optical detector in the display. The light emitting sheet may be configured to emit light when the object is in contact with a point on the sheet and the detector may be used to detect the emitted light and to locate the point of contact.

According to an embodiment of the present invention there is provided a system for detecting contact of an object with a display, the system including: a light emitting sheet on the display, the light emitting sheet being configured to emit light when the object is in contact with a point of contact on the sheet; and an optical detector in the display, the optical detector being configured to detect the emitted light and to locate the point of contact.

In one embodiment, the system includes an array of optical detectors including the optical detector, the array of optical detectors being embedded in the display and including another optical detector, the other optical detector being configured to detect and to locate another point of contact at a region of the light emitting sheet different from that corresponding to the optical detector.

In one embodiment, the light emitting sheet includes a polymer sheet having embedded in it a mechanoluminescent material.

In one embodiment, the light emitting sheet includes, as a major component, polydimethylsiloxane.

In one embodiment, the mechanoluminescent material includes, as a major component, ZnS:Cu.

In one embodiment, the light emitting sheet includes: a first electrode layer; a light emitting layer on the first electrode layer; a first polymer layer on the light emitting layer; a second polymer layer directly on the first polymer layer; a third electrode layer on the second polymer layer; and an insulating layer on the third electrode layer.

In one embodiment, the first polymer layer includes, as a major component, polyethylene terephthalate.

In one embodiment, the second polymer layer includes, as a major component, polyimide.

In one embodiment, the system includes a second electrode layer between the light emitting layer and the first polymer layer, the second electrode layer including a plurality of conductive areas, the conductive areas being insulated from each other.

In one embodiment, the light emitting layer is an organic light emitting diode layer.

In one embodiment, the organic light emitting diode layer is configured to emit infrared light.

In one embodiment, the first electrode layer is an infrared transparent electrode layer.

In one embodiment, the system includes a conductor connected to the first electrode layer and to the third electrode layer.

In one embodiment, the light emitting sheet includes: a first electrode layer; a light emitting layer on the first electrode layer; a force sensitive resistor layer on the light emitting layer; a third electrode layer on the force sensitive resistor layer; and an insulating layer on the third electrode layer.

In one embodiment, the force sensitive resistor layer includes conductive particles in a non-conductive medium.

In one embodiment, the light emitting layer is an infrared organic light emitting diode layer.

In one embodiment, the system includes a second electrode layer between the light emitting layer and the force sensitive resistor layer, the second electrode layer including a plurality of conductive areas, the conductive areas being insulated from each other.

In one embodiment, the system includes a voltage source having a first terminal connected to the first electrode layer and a second terminal connected to the third electrode layer.

In one embodiment, the light emitting sheet includes: a first electrode layer; an electroluminescent layer on the first electrode layer; and an insulating layer on the electroluminescent layer.

In one embodiment, the system includes an alternating current (AC) voltage source having a first terminal connected to the first electrode layer, and a second terminal connected to ground.

### BRIEF DESCRIPTION OF THE DRAWINGS

These and other features and advantages of the present invention will be appreciated and understood with reference to the specification, claims and appended drawings wherein:

FIG. 1 is an illustration of a system for detecting the presence of a finger;

FIG. 2 is an illustration of another system for detecting the presence of a finger;

FIG. 3 is an illustration of another system for detecting the presence of a finger;

FIG. 4 is a cross-sectional view of a system for detecting contact with a light emitting sheet including a mechanoluminescent material, according to an embodiment of the present invention;

FIG. 5A is an illustration of a mechanoluminescent material emitting light, according to an embodiment of the present invention;

FIG. 5B is a photograph of a sheet including a mechanoluminescent material emitting light, according to an embodiment of the present invention;

FIG. 5C is a photograph of a cross section of a sheet including a mechanoluminescent material, according to an embodiment of the present invention;

FIG. 5D is a photomicrograph graph of a cross section of a sheet including a mechanoluminescent material, according to an embodiment of the present invention;

FIG. 6A is a chart illustrating the spectrum of light emitted by mechanoluminescence by synthetic sapphire, according to an embodiment of the present invention;

FIG. 6B is a chart illustrating the spectrum of light emitted by mechanoluminescence by natural diamond, according to an embodiment of the present invention;

FIG. 6C is a chart illustrating the spectrum of light emitted by mechanoluminescence by quartz, according to an embodiment of the present invention;

FIG. 6D is a chart illustrating the spectrum of light emitted by mechanoluminescence by sodium chloride (NaCl), according to an embodiment of the present invention;

FIG. 6E is a chart illustrating the spectrum of light emitted by mechanoluminescence by magnesium oxide (MgO), according to an embodiment of the present invention;

FIG. 7 is a cross-sectional view of a light emitting sheet including a triboelectric generator, according to an embodiment of the present invention;

FIG. 8A is a cross-sectional view of a triboelectric generator in a first state, according to an embodiment of the present invention;

FIG. 8B is a cross-sectional view of a triboelectric generator in a second state, according to an embodiment of the present invention;

FIG. 8C is a cross-sectional view of a triboelectric generator in a third state, according to an embodiment of the present invention;

FIG. 8D is a cross-sectional view of a triboelectric generator in a fourth state, according to an embodiment of the present invention;

FIG. 9 is a cross-sectional view of a light emitting sheet including a triboelectric generator, according to another embodiment of the present invention;

FIG. 10 is a cross-sectional view of a light emitting sheet including a force sensitive resistor layer, according to an embodiment of the present invention;

FIG. 11 is an enlarged cross sectional view of a force sensitive resistor layer, according to an embodiment of the present invention;

FIG. 12 is a cross-sectional view of a light emitting sheet including a force sensitive resistor layer, according to an embodiment of the present invention;

FIG. 13 is a cross-sectional view of a light emitting sheet including an electroluminesce t layer, according to another embodiment of the present invention;

FIG. 14A is an illustration of two points of contact with a light emitting sheet, according to an embodiment of the present invention;

FIG. 14B is an illustration of light emitted at the two points of contact of FIG. 14B, according to an embodiment of the present invention;

FIG. 15A is an illustration of two points of contact with a light emitting sheet including a patterned electrode, according to an embodiment of the present invention;

FIG. 15B is an illustration of light emitted at the two points of contact of FIG. 15B, according to an embodiment of the present invention; and

FIG. 16 is a block diagram of a light emitting sheet employed with an array of optical detectors, according to an embodiment of the present invention.

### DETAILED DESCRIPTION

The detailed description set forth below in connection with the appended drawings is intended as a description of exemplary embodiments of a technique for generating localized light source for an embedded optical sensor array provided in accordance with the present invention and is not intended to represent the only forms in which the present invention may be constructed or utilized. The description sets forth the features of the present invention in connection with the illustrated embodiments. It is to be understood, however, that the same or equivalent functions and structures may be accomplished by different embodiments that are also intended to be encompassed within the spirit and scope of the invention. As denoted elsewhere herein, like element numbers are intended to indicate like elements or features.

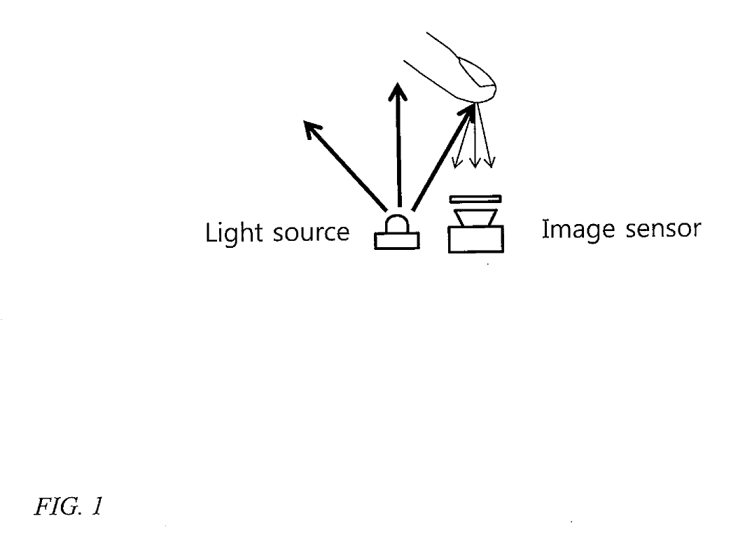

Related art embodiments for detecting a user's touch on a display panel, and locating the point at which the display is touched, may require relatively high power sources of illumination providing, e.g., infrared (IR) light over the entire space in front of the display that must stay on constantly or at least periodically. For example, referring to FIG. 1, in one related art embodiment, a single light source illuminates a region above a display and the presence of a finger is detected by sensing reflections, of light produced by the light source, from the finger. The light source may be sufficiently powerful so that its reflection from outside the display can be detected, and the light source may always be on. As a result, the light source may consume a significant amount of power even when there is no touch event.

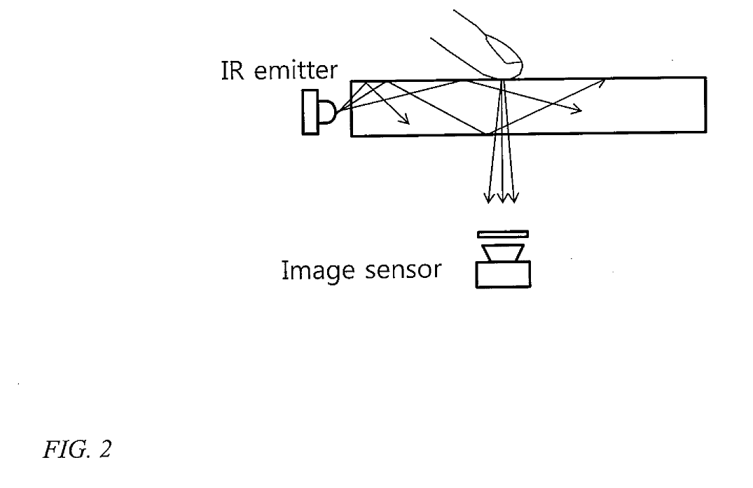

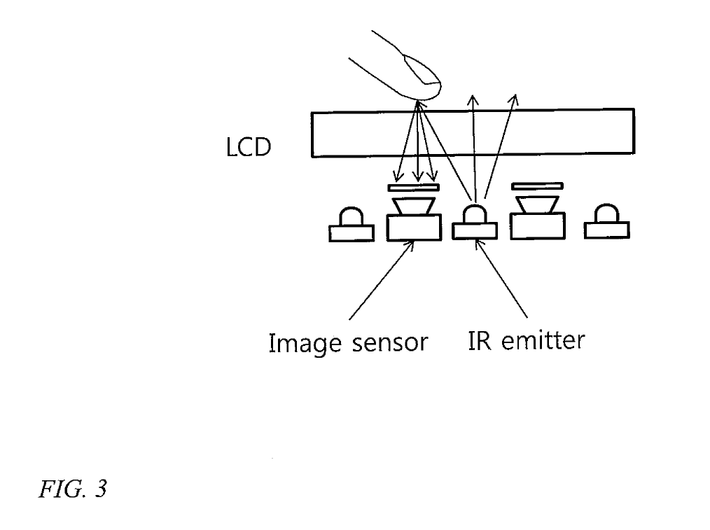

In another related art embodiment illustrated in FIG. 2, IR light is injected from the edge of a display, waveguided within a sheet of glass. When the glass is touched, the guided IR light may be redirected out of the waveguide toward an image sensor which detects the IR light to locate the position of the touch event on the display screen. In another related art embodiment illustrated in FIG. 3, an IR source is incorporated into the backlight unit of a liquid crystal display (LCD). This light is transmitted through the LCD panel to the outside of the display, where it is reflected by the object (e.g., finger) near the display screen.

Embodiments of the present invention produce light at or near a point of contact of an object (e.g., a finger) with a display. The display may be an organic light emitting diode (OLED) display or an LCD. A sheet that is transparent to visible light is secured to the display, i.e., between the display and the user. The sheet is configured to act as a local light source, i.e., to emit light when touched by an object, e.g., the user's finger, and the light is emitted only in the vicinity of the point of contact. Infrared or other spectrums of light may be emitted. An optical detector, or an array of optical detectors configured to detect the spectrum of light, may be embedded in the display, and may be used to infer, from the distribution of detected infrared light, the location of the point of contact, i.e., to locate the point of contact. The sheet may generate light, in response to contact, by any of several mechanisms.

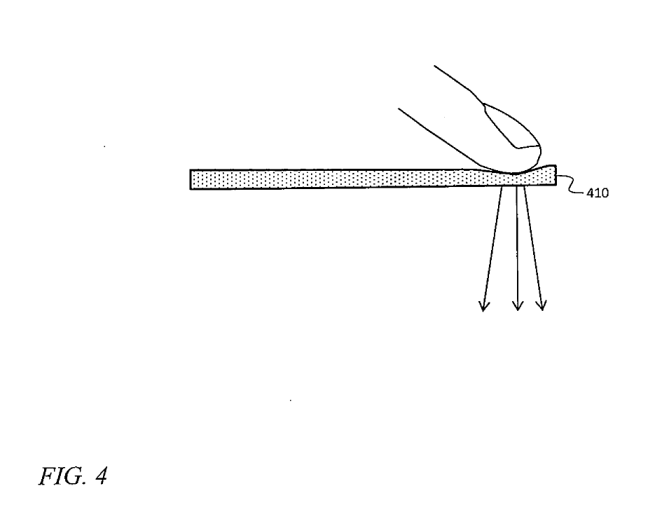

Referring to FIG. 4, in one embodiment the light emitting sheet 410 is a sheet (e.g., a polymer sheet) including a mechanoluminescent (ML) material that emits light when deformed. The mechanoluminescent material may be embedded in a high elastic modulus material such as polydimethylsiloxane (PDMS). A high elastic modulus material may efficiently transfer the mechanical stress from the touch event (i.e., from contact of an object with the sheet) to the ML material, causing the ML material to be deformed and to emit light. The generated light may be in the IR or in the visible range. PDMS may be transparent to visible light and therefore a PDMS sheet may be secured directly over a display panel, without obscuring the user's view of the panel. ML materials may emit a first light pulse during the compression or stretching process and a second light pulse during the relaxation process. The ML materials may emit no light in a static state, e.g., while the user continues to press on a display with a constant force.

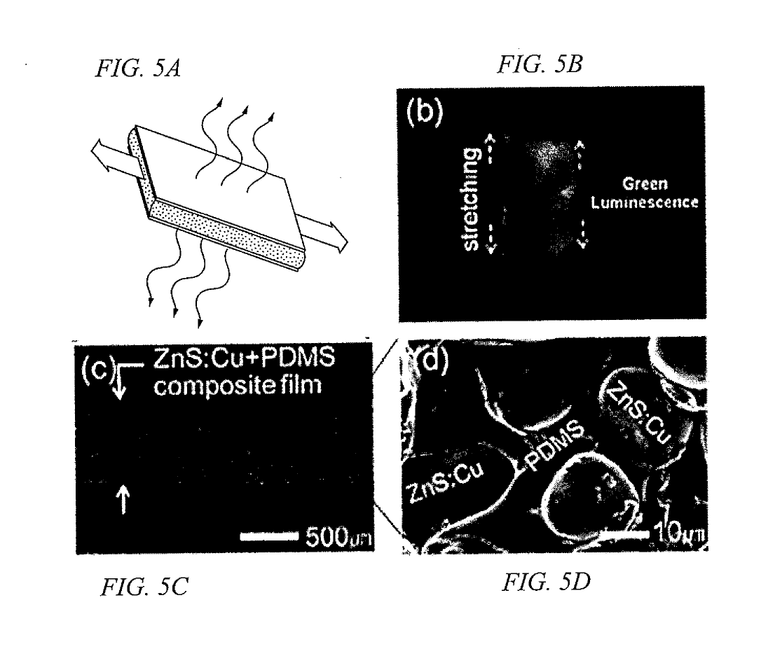

In one embodiment, deformation of the sheet caused by contact of a finger or other object (as illustrated in FIG. 5A) may result in luminescence (i.e., emission of light) as shown in FIG. 5B.

FIGS. 5C and 5D show, at lower and higher magnification, respectively, an embodiment in which the light emitting sheet is a composite film containing the ML material zinc sulfide doped with copper (or “ZnS:Cu”). The light emitting sheet emits a green luminescence having a wavelength λ when the material is stretched. In this embodiment, the optical detectors may be configured to only respond to light having the wavelength λ.

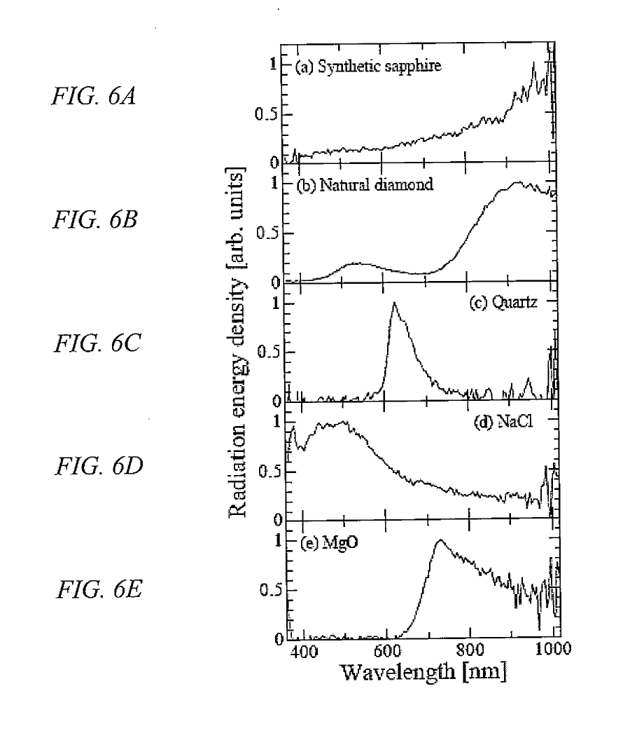

Referring to FIGS. 6A-6E, in some embodiments, ML materials that emit IR light may be used. For example, in some embodiments, a triboluminescent material that emits infrared light may be utilized. Certain triboluminescent materials emit IR light when chemical bonds in the material are broken as a result of the material being compressed or stretched. FIGS. 6A-6E depict the wavelengths of light emitted from various triboluminescent materials including ones containing synthetic sapphire (FIG. 6A), natural diamond (FIG. 6B), quartz (FIG. 6C), sodium chloride (NaCl) (FIG. 6D), and magnesium oxide (MgO) (FIG. 6E). Infrared light, being invisible to the user, may be unlikely to interfere with the user's viewing of the contents of the display and therefore allow for unimpeded functionality.

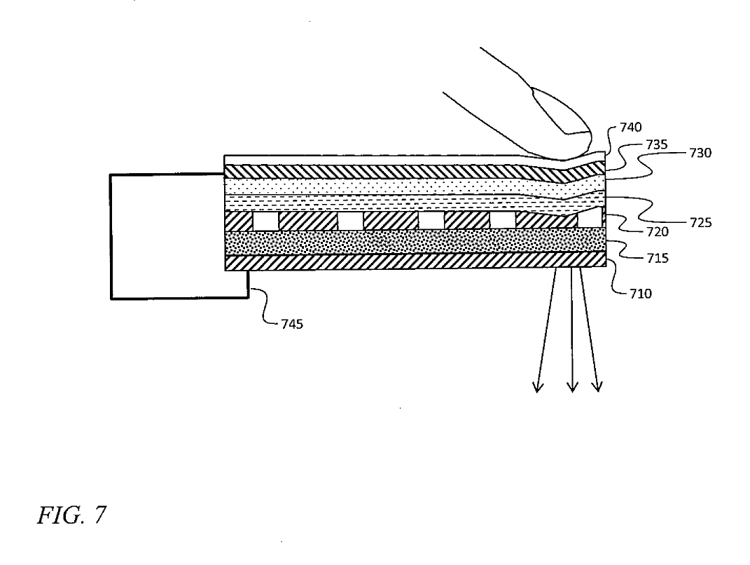

Referring to FIG. 7, in one embodiment the light emitting sheet includes a triboelectric generator (TEG) connected to a light emitter. The TEG generates current when it is mechanically compressed, which turns on a light emitter. The light emitting sheet includes a first electrode layer 710, a light emitting layer 715 on the first electrode layer 710, a second electrode layer 720 on the light emitting layer 715, a first polymer layer 725 on the light emitting layer 715, a second polymer layer 730 directly on the first polymer layer 725, a third electrode layer 735 on the second polymer layer 730, and an insulating layer 740 on the third electrode layer 735. The first polymer layer 725 may include, e.g., polyethylene terephthalate, and the second polymer layer 730 may include, e.g., polyimide (e.g., KAPTON™). In this embodiment, the first electrode layer 710 is electrically coupled to the third electrode layer 735 by the conductor 745.

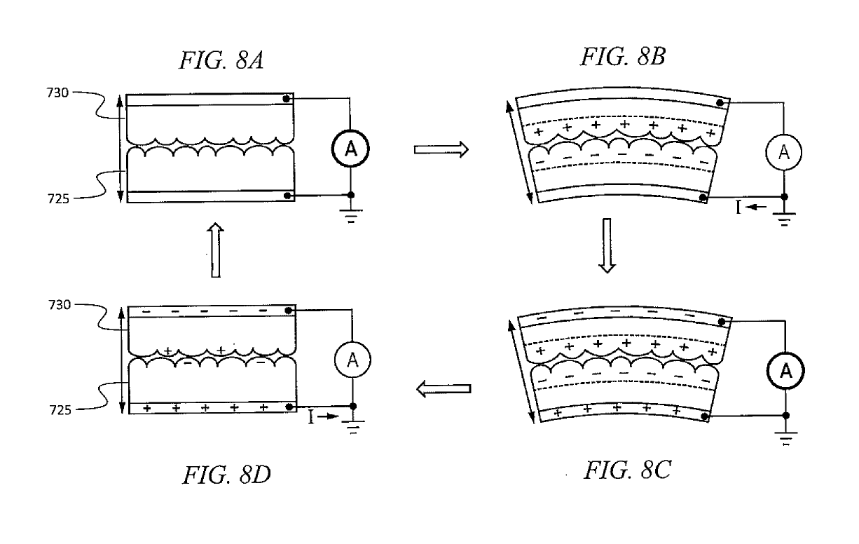

Referring to FIGS. 8A-8D, the triboelectric generator includes polymer layers 725, 730 which may be sandwiched between two electrodes. In one embodiment, the two polymer layers 225, 730 may be made of two different polymer materials. A potential between the layers is created when an external force, e.g., pressure from a finger, is applied to the structure. The external force causes a deforming of the triboelectric generator from the configuration of FIG. 8A to that of FIG. 8B and friction between the two films generates equal and opposite charges at the interface between the two polymer layers, causing the change in potential. In addition, mechanical deformation changes the capacitance of the system. A current may then flow through an external current path, until, in the configuration of FIG. 8C, charge has accumulated on the electrodes to the extent that they are at the same potential, at which point the current ceases to flow. When the external force is removed, the triboelectric generator returns to the physical configuration of FIG. 8D, and current flows in the reverse direction until the electrodes are again at the same potential, as in the configuration of FIG. 8A. Thus, the TEG may generate a current during the compression or stretching process and a reverse current during the relaxation process.

Referring again to FIG. 7, the light emitting layer 715 may be a transparent infrared organic light emitting diode layer (OLED layer). Current may flow, when the TEG is deformed by pressure from a finger, through the light emitting layer 715, and through a conductor 745, connected to the first electrode layer 710 and to the third electrode layer 735, which forms a current return path. The second electrode layer 720 may be patterned, e.g., it may include, or be composed of, a plurality of conductive areas, the conductive areas being insulated from each other. Insulating the conductive areas from each other prevents current from flowing laterally through the second electrode 720, thus causing the light emitting layer 715 to emit light at a point distant from the point of contact.

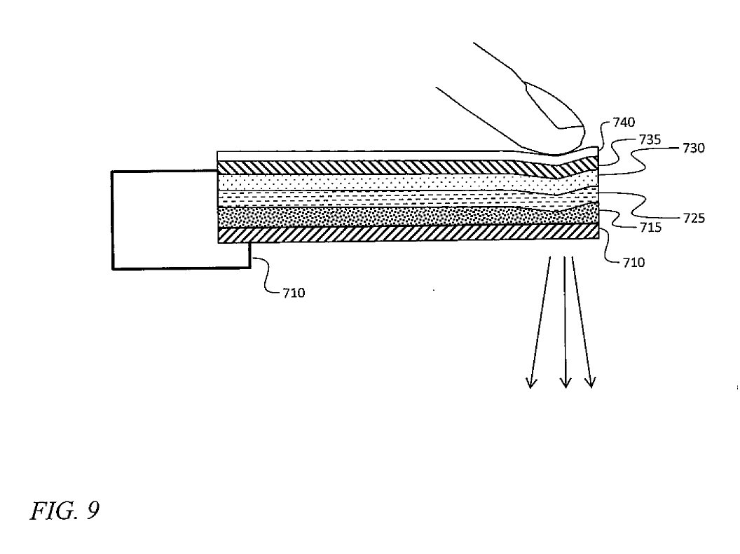

Referring to FIG. 9, in one embodiment, the second electrode layer 720 is omitted from the structure. This allows for current to flow directly between the polymer layers 725, 730 to the light emitting layer 715.

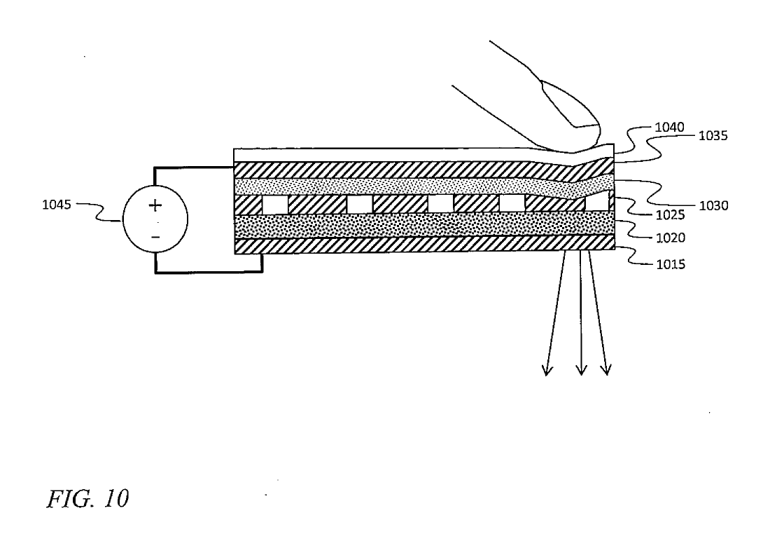

Referring to FIG. 10, in one embodiment the light emitting sheet utilizes a force sensitive resistor (FSR) layer. The FSR light emitting sheet includes a first electrode layer 1015, a light emitting layer 1020 on the first electrode layer 1015, a second electrode layer 1025 on the light emitting layer 1020, a force sensitive resistor (FSR) layer 1030 on the second electrode layer 1025, a third electrode layer 1035 on the FSR layer 1030, and an insulating layer 1040 on the third electrode layer 1035. A power source 1045 has a first terminal connected to the first electrode layer 1015 and a second terminal connected to the third electrode layer 1035. The light emitting layer 1020 may be a transparent infrared OLED. The second electrode layer 1025 may be patterned, e.g., it may include, or be composed of, a plurality of conductive areas, the conductive areas being insulated from each other, to prevent current from flowing laterally through the second electrode layer 1025 and from thus causing the light emitting layer 1020 to emit light at a point distant from the point of contact.

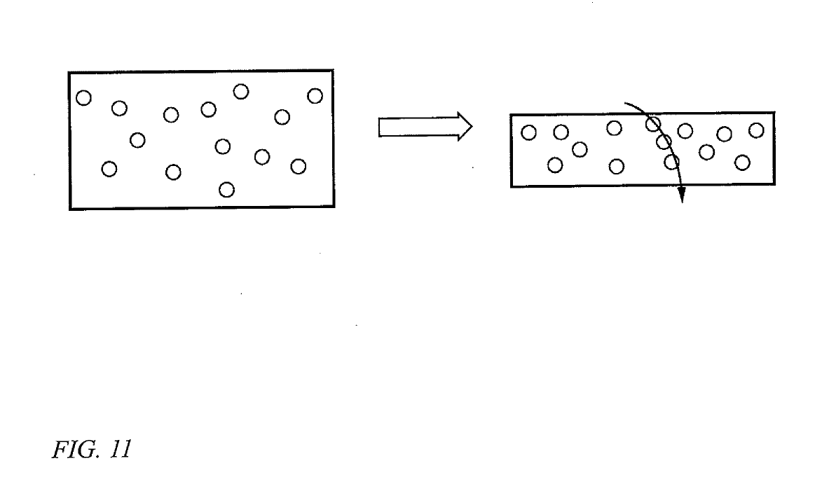

Referring to FIG. 11, an exemplary FSR material includes conductive particles in a non-conductive medium. When the FSR is compressed, the conductive particles are pushed to be in closer proximity to each other and the material becomes lower in resistance and begins to conduct current. The conductivity of the FSR may be anisotropic, e.g., higher in a direction perpendicular to the FRS layer 1030 (FIG. 10) than in a direction parallel to the FSR layer 1030, when the FSR layer is compressed.

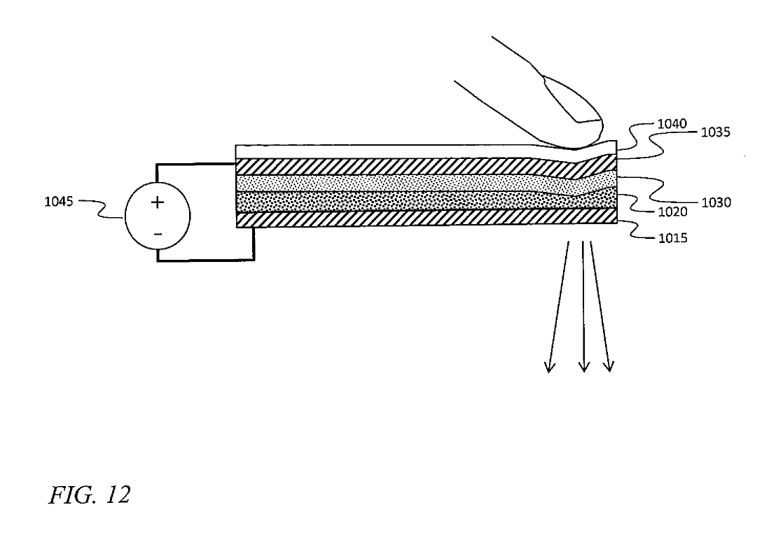

Referring again to FIG. 10, when the FSR layer 1030 is compressed at the point of contact, current driven by the power source 1045 may flow more readily through the FSR layer 1030 at the point of contact, through the light emitting layer 1020, and back to the power source. If the power source 1045 is a voltage source, the brightness of the OLED, when the FSR layer 1030 is compressed, may be proportional to the pressure. If the power source 1045 is a current source, either the current is able to conduct, when the FSR layer 1030 is compressed, and the OLED turns on at a brightness corresponding to the current generated by the current source, or the OLED remains off. Referring to FIG. 12, in one embodiment, the second electrode layer 1025 is omitted from the structure.

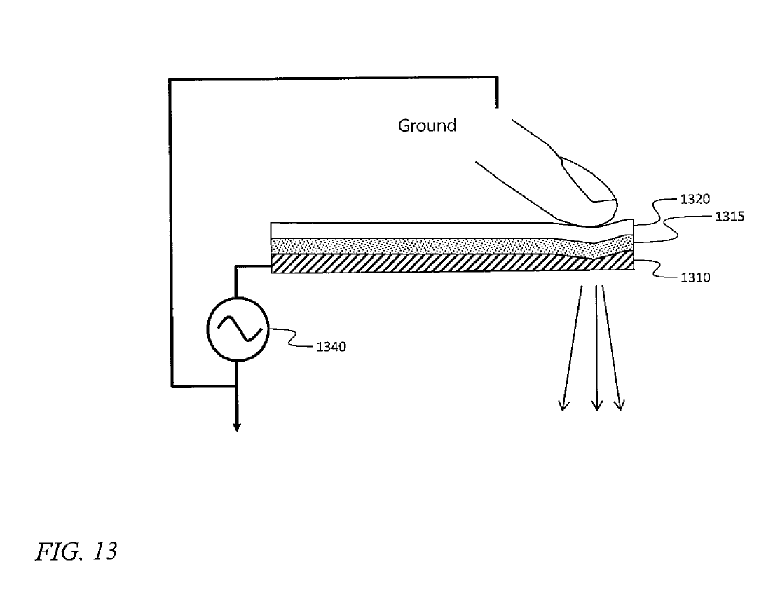

Referring to FIG. 13, in one embodiment, the light emitting sheet utilizes an electroluminescent (EL) layer to produce light. The light emitting sheet includes a first electrode layer 1310, an electroluminescent (EL) layer 1315 on the first electrode layer, and an insulating layer (or “dielectric” layer) 1320 on the electroluminescent layer 1315. The first electrode layer 1310 is biased with an alternating current (AC) voltage source. When a conductive object, such as a finger, is placed on the substrate, the electric circuit completes where the touch event is, and the EL layer emits light. The wavelength of the emitted light may depend on the EL material chosen. In one embodiment, the EL material includes powdered zinc sulfide doped with copper or silver or thin-film zinc sulfide doped with manganese.

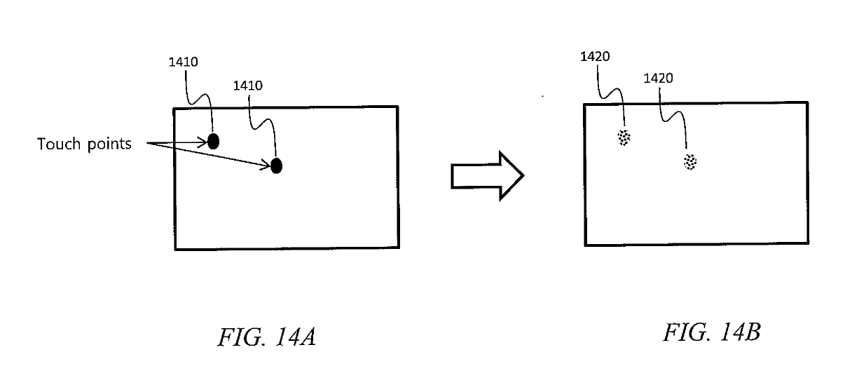

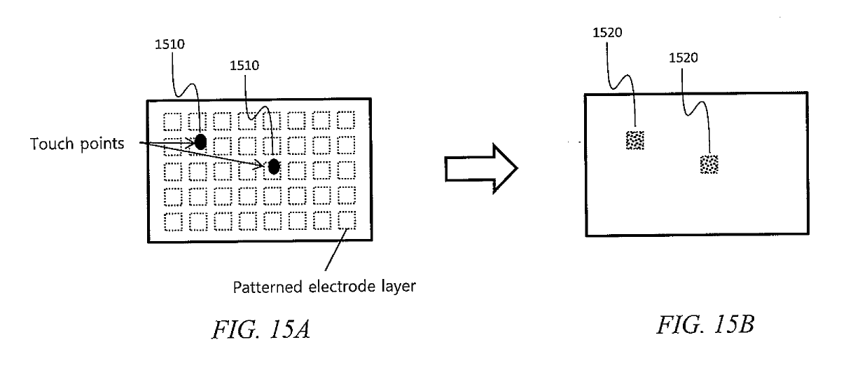

In the embodiments of FIGS. 4, 9, 12, and 13, the emission of light from the light emitting sheet may be confined to a region at or near the point of contact, as illustrated in FIGS. 14A and 14B. One or more points of contact (or “touch points”) 1410 between a user's finger or other object and the sheet may result in light being emitted from corresponding emission regions 1420. Simultaneous contact at two or more points of the display may result in light being emitted simultaneously from two or more regions 1420; thus, it may be possible for a user to interact with the display using more than one finger simultaneously. In the embodiments of FIGS. 7 and 10, patterned electrodes, or electrode layers including, or composed of, a plurality of conductive areas that are insulated from each other, may be used. Referring to FIGS. 15A and 15B, in an embodiment with a patterned electrode layer, the touch of a user's finger (e.g., at the points of contact 1510) may result in conductive areas of the patterned electrode acting as sources or sinks of electrical current, resulting in emission regions 1520 corresponding to the size and shape of each affected conductive area.

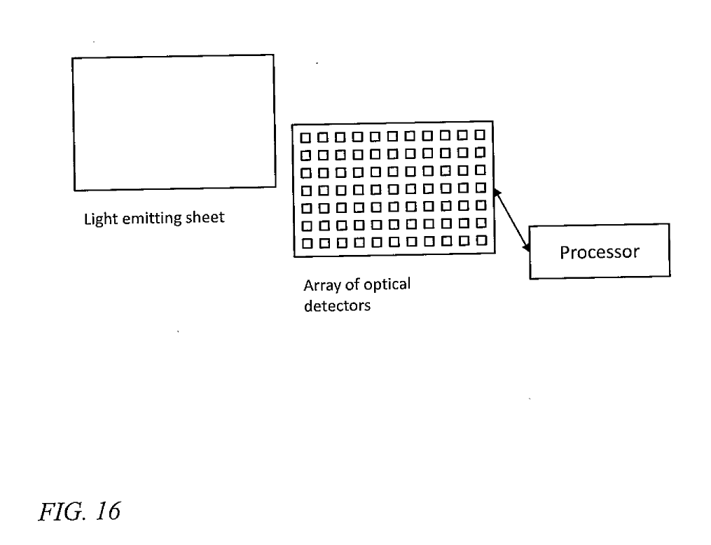

Referring to FIG. 16, a light emitting sheet may be employed with an array of optical detectors embedded in a display (or “an embedded optical sensor array”). A processor may be connected to the array of optical sensors, to process the signals generated by the optical sensors.

According to an embodiment of the present invention there is provided a system for detecting contact of an object with a display, the system including: a light emitting sheet on the display, the light emitting sheet being configured to emit light when the object is in contact with a point on the sheet; and an optical detector in the display, the optical detector being configured to detect the emitted light and to locate the point of contact.

In one embodiment, the system includes an array of optical detectors including the optical detector, the array of optical detectors being embedded in the display and including another optical detector, the other optical detector being configured to detect and locate another point of contact at a region of the sheet different from that corresponding to the optical detector.

Each layer of each embodiment described herein may be transparent to visible light, so that the sheet may be transparent to visible light and so that a user may be able to view the display through the sheet. Moreover, any layers that are between a light emitting layer and the display may be infrared transparent layers, i.e., each of these layers may transmit between 5.0% and 100.0% of infrared light incident upon it. For example, the first electrode layer 710 of the embodiment of FIG. 9 may be an infrared transparent electrode layer.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section, without departing from the spirit and scope of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that such spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the inventive concept. As used herein, the terms “substantially,” “about,” and similar terms are used as terms of approximation and not as terms of degree, and are intended to account for the inherent deviations in measured or calculated values that would be recognized by those of ordinary skill in the art. As used herein, the term “major component” means a component constituting at least half, by weight, of a composition, and the term “major portion”, when applied to a plurality of items, means at least half of the items.

As used herein, the singular forms “a”, “an” and “the” are intended to include the plural forms as well, unless the context clearly indicates otherwise. It will be further understood that the terms “comprises” and/or “comprising”, when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list. Further, the use of “may” when describing embodiments of the inventive concept refers to “one or more embodiments of the present invention”. Also, the term “exemplary” is intended to refer to an example or illustration.

As used herein, the terms “use,” “using,” and “used” may be considered synonymous with the terms “utilize,” “utilizing,” and “utilized,” respectively.

It will be understood that when an element or layer is referred to as being “on”, “connected to”, “coupled to”, or “adjacent to” another element or layer, it may be directly on, connected to, coupled to, or adjacent to the other element or layer, or one or more intervening elements or layers may be present. In contrast, when an element or layer is referred to as being “directly on”, “directly connected to”, “directly coupled to”, or “immediately adjacent to” another element or layer, there are no intervening elements or layers present.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein.

Components of the system for locating a point of contact according to embodiments of the present invention described herein may be implemented utilizing any suitable hardware, firmware (e.g. an application-specific integrated circuit), software, or a suitable combination of software, firmware, and hardware. For example, various components may be formed on one integrated circuit (IC) chip or on separate IC chips. Further, the various components may be implemented on a flexible printed circuit film, a tape carrier package (TCP), a printed circuit board (PCB), or formed on one substrate. Further, various components may each be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the exemplary embodiments of the present invention.

Although exemplary embodiments of a technique for generating localized light source for an embedded optical sensor array have been specifically described and illustrated herein, many modifications and variations will be apparent to those skilled in the art. Accordingly, it is to be understood that a technique for generating localized light source for an embedded optical sensor array constructed according to principles of this invention may be embodied other than as specifically described herein. The invention is also defined in the following claims, and equivalents thereof.

What is claimed is:

1. A system for detecting contact of an object with a display, the system comprising:
a light emitting sheet on the display, the light emitting sheet being configured to emit light when the object is in contact with a point of contact on the sheet; and
an optical detector in the display,
the optical detector being configured to detect the emitted light and to locate the point of contact.

2. The system of claim 1, comprising an array of optical detectors comprising the optical detector, the array of optical detectors being embedded in the display and comprising another optical detector, the other optical detector being configured to detect and to locate another point of contact at a region of the light emitting sheet different from that corresponding to the optical detector.

3. The system of claim 1, wherein the light emitting sheet comprises a polymer sheet having embedded in it a mechanoluminescent material.

4. The system of claim 3 wherein the light emitting sheet comprises, as a major component, polydimethylsiloxane.

5. The system of claim 4, wherein the mechanoluminescent material comprises; as a major component, ZnS:Cu.

6. The system of claim 1, wherein the light emitting sheet comprises:
a first electrode layer;
a light emitting layer on the first electrode layer;
a first polymer layer on the light emitting layer;
a second polymer layer directly on the first polymer layer;
a third electrode layer on the second polymer layer; and
an insulating layer on the third electrode layer.

7. The system of claim 6 wherein the first polymer layer comprises, as a major component, polyethylene terephthalate.

8. The system of claim 7, wherein the second polymer layer comprises, as a major component, polyimide.

9. The system of claim 6, further comprising a second electrode layer between the light emitting layer and the first polymer layer,
the second electrode layer comprising a plurality of conductive areas, the conductive areas being insulated from each other.

10. The system of claim 6, wherein the light emitting layer is an organic light emitting diode layer.

11. The system of claim 10, wherein the organic light emitting diode layer is configured to emit infrared light.

12. The system of claim 6, wherein the first electrode layer is an infrared transparent electrode layer.

13. The system of claim 6, further comprising a conductor connected to the first electrode layer and to the third electrode layer.

14. The system of claim 1, wherein the light emitting sheet comprises:
a first electrode layer;
a light emitting layer on the first electrode layer;
a force sensitive resistor layer on the light emitting layer;
a third electrode layer on the force sensitive resistor layer; and
an insulating layer on the third electrode layer.

15. The system of claim 14, wherein the force sensitive resistor layer comprises conductive particles in a non-conductive medium.

16. The system of claim 15, wherein the light emitting layer is an infrared organic light emitting diode layer.

17. The system of claim 14, further comprising a second electrode layer between the light emitting layer and the force sensitive resistor layer,
the second electrode layer comprising a plurality of conductive areas, the conductive areas being insulated from each other.

18. The system of claim 14, further comprising a voltage source having a first terminal connected to the first electrode layer and a second terminal connected to the third electrode layer.

19. The system of claim 1, wherein the light emitting sheet comprises:
a first electrode layer;
an electroluminescent layer on the first electrode layer; and
an insulating layer on the electroluminescent layer.

20. The system of claim 19, further comprising an alternating current (AC) voltage source having a first terminal connected to the first electrode layer, and a second terminal connected to ground.
